(19) United States
(12) Patent Application Publication
(10) Pub. No.: US 2026/0269190 A1
(43) Pub. Date: Sep. 10, 2026

(54) Bottom Clipped Stud-Socket Assemblies for Dielectric Etch Chamber Electrodes

(71) Applicant: Lam Research Corporation, Fremont, CA (US)

(72) Inventors: Gordon Peng, Fremont, CA (US); I-Chi Lin, Fremont, CA (US)

(21) Appl. No.: 19/165,526

(22) PCT Filed: Oct. 23, 2024
(86) PCT No.: PCT/US24/52671

§ 371 Date: Sep. 15, 2025

Related U.S. Application Data
(60) Provisional application No. 63/601,037, filed on Nov. 20, 2023.
(60) Provisional application No. 63/653,157, filed on May 29, 2024.

(51) Int. Cl. H01J 37/32; H10P 72/72

(52) U.S. Cl. CPC H01J 37/32577; H10P 72/722

(57) ABSTRACT

A stud-socket assembly includes: a stud pin having a head portion, a main body, and a neck portion that connects the head portion to the main body; a socket having a cylindrical interior volume, and having an upper opening through which the stud pin is disposed, the upper opening having an inner diameter that is less than the outer diameter of the head portion of the stud pin by at least 0.005 inch; a plurality of Belleville washers that circumferentially surround the main body of the stud pin; a retainer attached to the second end of the main body of the stud pin, the retainer configured to retain the plurality of Belleville washers within the cylindrical interior volume of the socket.

### BACKGROUND OF THE INVENTION

Commonly used and critical processes employed in the fabrication of semiconductor devices include dry plasma etching, reactive ion etching, and ion milling techniques. Plasma etching, in particular, allows a vertical etch rate to be made much greater than a corresponding horizontal etch rate so that a resulting aspect ratio of the etched features can be adequately controlled.

During the plasma etching process, a plasma is formed above the masked surface of the wafer by adding large amounts of energy to a gas at relatively low pressure, resulting in an ionized gas. By adjusting the electrical potential of the substrate to be etched, charged species in the plasma can be directed to impinge substantially normally upon the wafer wherein materials in the unmasked regions of the wafer are removed.

The etching process can often be made more effective by using gases that are chemically reactive with the material being etched. Reactive ion etching (RIE) combines energetic etching effects of the plasma with a chemical etching effect of the gas. A reactive ion etching system typically consists of an etching chamber with an upper electrode (an anode) and a lower electrode (a cathode) positioned therein. The cathode is negatively biased with respect to the anode and the chamber walls. The wafer to be etched is covered by a suitable mask and placed directly on the cathode (e.g., typically an electrostatic chuck). A chemically reactive gas such as carbon tetrafluoride (CF4), trifluoromethane (CHF3), chlorotrifluoromethane (CClF3), sulfur hexafluoride (SF6), or mixtures thereof, is combined with oxygen (O2), nitrogen (N2), helium (He), or argon (Ar) and introduced into the etching chamber and maintained at a pressure which is typically in the millitorr range.

The upper electrode is typically provided with gas apertures which permit the input gas to be uniformly dispersed through the electrode into the chamber. The electric field established between the anode and the cathode dissociates the reactive gas, thus forming a plasma. The surface of the wafer is etched by chemical interaction with the active ions and by momentum transfer of the ions striking unmasked portions of the wafer. The electric field created by the electrodes will attract the ions to the cathode, causing the ions to strike the wafer in a predominantly vertical direction so that the process produces well-defined vertically etched side walls.

### SUMMARY OF THE INVENTION

Broadly speaking, implementations of the present disclosure are drawn to bottom clipped stud-socket assemblies for dielectric etch chamber electrodes. More specifically, the stud-socket assemblies facilitate secure connection of top electrode components to a backing plate in a plasma process chamber. Some example embodiments are described below.

In some implementations, a stud-socket assembly for connecting an upper electrode or annular shroud to a backing plate in a plasma process chamber is provided, including: a stud pin having a head portion, a main body, and a neck portion that connects the head portion to the main body; wherein the neck portion being a cylindrical portion having a first diameter; wherein the main body being substantially cylindrically shaped and having a shoulder at a first end that connects to the neck portion, and further having a groove at a second end opposite the first end, and a region extending from the shoulder to the groove having a constant second diameter that is greater than the first diameter; wherein the head portion having an outer diameter that is greater than the second diameter; a socket having a top section, a middle section, and a bottom section; wherein the middle section and the bottom section being tubular-shaped sections that circumferentially surround a cylindrical interior volume of the socket, such that the middle section and the bottom section have a same inner diameter, wherein a top surface of the cylindrical interior volume is defined at an intersection of the top section and the middle section; wherein the top section being a disc-shaped section, and further having an opening through which the stud pin is disposed, the opening having an inner diameter that is less than the outer diameter of the head portion of the stud pin by at least 0.005 inch; an E-clip fitted to the groove of the main body of the stud pin; a plurality of Belleville washers that circumferentially surround the main body of the stud pin between the E-clip and the top surface of the cylindrical interior volume of the socket; wherein the E-clip and the plurality of Belleville washers are configured to be disposed inside of the cylindrical interior volume of the socket.

In some implementations, the inner diameter of the opening being less than the outer diameter of the head portion of the stud pin defines an interference such that the head portion cannot be press fit through the opening for assembly.

In some implementations, the head portion of the stud pin is configured to be engaged by a camshaft disposed in the backing plate.

In some implementations, an external surface of the bottom section being threaded to enable the socket to be screwed into the upper electrode.

In some implementations, the stud-socket assembly of further includes: a first flat washer disposed between the Belleville washers and the E-clip; a second flat washer disposed between the Bellville washers and the top surface of the cylindrical interior volume.

In some implementations, the opening in the top section of the socket having taper relief that facilitates tilting articulation of the stud pin.

In some implementations, the bottom section of the socket having a minimum radial thickness of at least about 0.045 inch.

In some implementations, the Belleville washers are arranged in series.

In some implementations, the socket is fabricated from a Torlon material.

In some implementations, the stud pin is fabricated from a stainless steel material.

In some implementations, a stud-socket assembly for connecting an upper electrode or annular shroud to a backing plate in a plasma process chamber is provided, including: a stud pin having a head portion, a main body, and a neck portion that connects the head portion to the main body; wherein the neck portion being a cylindrical portion having a first diameter; wherein the main body being substantially cylindrically shaped and having a shoulder at a first end that connects to the neck portion, and further having a groove at a second end opposite the first end, and a region extending from the shoulder to the groove having a constant second diameter that is greater than the first diameter; wherein the head portion having an outer diameter in the range of about 0.16 to 0.17 inch; a socket having a top section, a middle section, and a bottom section; wherein the middle section and the bottom section being tubular-shaped sections that circumferentially surround a cylindrical interior volume of the socket, such that the middle section and the bottom section have a same inner diameter, wherein a top surface of the cylindrical interior volume is defined at an intersection of the top section and the middle section; wherein the top section being a disc-shaped section, and further having an opening through which the stud pin is disposed, the opening having an inner diameter that is less than the outer diameter of the head portion of the stud pin by at least 0.007 inch, and in the range of about 0.15 to 0.16 inch; an E-clip fitted to the groove of the main body of the stud pin; a plurality of Belleville washers that circumferentially surround the main body of the stud pin between the E-clip and the top surface of the cylindrical interior volume; a first flat washer disposed between the Belleville washers and the E-clip; a second flat washer disposed between the Bellville washers and the top surface of the cylindrical interior volume; wherein the E-clip, the first flat washer, the second flat washer, and the plurality of Belleville washers are configured to be disposed inside of the cylindrical interior volume of the socket.

In some implementations, a stud-socket assembly is provided for connecting an upper electrode or annular shroud to a backing plate in a plasma process chamber, including: a stud pin having a head portion, a main body, and a neck portion that connects the head portion to the main body; wherein the neck portion being a cylindrical portion having a first diameter; wherein the main body being substantially cylindrically shaped at a second diameter that is greater than the first diameter, and having a shoulder at a first end that connects to the neck portion, and a second end opposite the first end; wherein the head portion having an outer diameter that is greater than the second diameter; a socket having a cylindrical interior volume, and having an upper opening through which the stud pin is disposed, the upper opening having an inner diameter that is less than the outer diameter of the head portion of the stud pin by at least 0.005 inch; a plurality of Belleville washers that circumferentially surround the main body of the stud pin; a retainer attached to the second end of the main body of the stud pin, the retainer configured to retain the plurality of Belleville washers within the cylindrical interior volume of the socket.

In some implementations, the inner diameter of the upper opening being less than the outer diameter of the head portion of the stud pin defines an interference such that the head portion cannot be press fit through the opening for assembly.

In some implementations, the head portion of the stud pin is configured to be engaged by a camshaft disposed in the backing plate.

In some implementations, an external surface of the socket being threaded to enable the socket to be screwed into the upper electrode.

In some implementations, the stud-socket assembly further includes: a first flat washer disposed between the Belleville washers and the retainer; a second flat washer disposed between the Belleville washers and the upper opening of the socket.

In some implementations, the upper opening of the socket having taper relief that facilitates tilting articulation of the stud pin.

In some implementations, the Belleville washers are arranged in series.

In some implementations, the socket is fabricated from a Torlon material.

In some implementations, the stud pin is fabricated from a stainless steel material.

In some implementations, the retainer is one of an E-clip, a poodle clip, or a snap ring.

In some implementations, a stud-socket assembly is provided for connecting an upper electrode or annular shroud to a backing plate in a plasma process chamber, including: a stud pin having a head portion, a main body, and a neck portion that connects the head portion to the main body; wherein the neck portion being a cylindrical portion having a first diameter; wherein the main body being substantially cylindrically shaped at a second diameter that is greater than the first diameter, and having a first end that connects to the neck portion, and a second end opposite the first end; wherein the head portion having an outer diameter that is greater than the second diameter; a socket having a cylindrical interior volume, and having an upper opening through which the stud pin is disposed, the upper opening having an inner diameter that is less than the outer diameter of the head portion of the stud pin by at least 0.005 inch; a plurality of Belleville washers that circumferentially surround the main body of the stud pin; wherein the socket having a lower opening, an inner diameter of the lower opening being greater than an outer diameter of the Belleville washers; a retainer attached to the second end of the main body of the stud pin, the retainer configured to retain the plurality of Belleville washers within the cylindrical interior volume of the socket.

In some implementations, the inner diameter of the upper opening being less than the outer diameter of the head portion of the stud pin defines an interference such that the head portion cannot be press fit through the opening for assembly.

In some implementations, the head portion of the stud pin is configured to be engaged by a camshaft disposed in the backing plate.

In some implementations, an external surface of the socket being threaded to enable the socket to be screwed into the upper electrode.

In some implementations, the stud-socket assembly further includes: a first flat washer disposed between the Belleville washers and the retainer; a second flat washer disposed between the Belleville washers and the upper opening of the socket.

In some implementations, the upper opening of the socket having taper relief that facilitates tilting articulation of the stud pin.

In some implementations, the Belleville washers are arranged in series.

In some implementations, the main body of the stud pin having a circumferential groove defined at the second end of the main body, and wherein the retainer is fitted to the circumferential groove.

In some implementations, the circumferential groove has a substantially rectangular or substantially semi-circular cross-section.

In some implementations, the retainer is one of an E-clip, a poodle clip, or a snap ring.

The foregoing is merely a summary of certain implementations, and it will be appreciated that further implementations will be apparent upon a full understanding of the present disclosure.

### BRIEF DESCRIPTION OF DRAWINGS

FIG. 1A shows a partial cross-sectional view of a showerhead electrode assembly along a diameter for a capacitively coupled plasma reaction chamber, in accordance with implementations of the disclosure.

FIG. 1B shows a partial cross-sectional view of the showerhead electrode assembly of FIG. 1A along another diameter, in accordance with implementations of the disclosure.

FIG. 2A is a three-dimensional representation of an exemplary cam lock for attaching an outer electrode, an inner electrode and an annular shroud in the showerhead electrode assembly shown in FIGS. 1A and 1B, in accordance with implementations of the disclosure.

FIG. 2B is a partial cross-sectional view of the exemplary cam lock of FIG. 2A, in accordance with implementations of the disclosure.

FIG. 3 is a cross-sectional view of a stud-socket assembly, in accordance with implementations of the disclosure.

FIG. 4 is a plan view of a stud-socket assembly, in accordance with implementations of the disclosure.

FIG. 5A is a cutaway side view of a socket, in accordance with implementations of the disclosure.

FIG. 5B is a cutaway perspective view of a socket, in accordance with implementations of the disclosure.

FIG. 6 is a schematic cross-section of a stud pin, in accordance with implementations of the disclosure.

FIG. 7A is a cross-sectional view of a stud-socket assembly in an installed configuration, in accordance with implementations of the disclosure.

FIG. 7B is a cross-sectional view of a stud-socket assembly in an installed configuration, in accordance with implementations of the disclosure.

FIG. 8A illustrates a top view of an E-clip, in accordance with implementations of the disclosure.

FIG. 8B illustrates a top view of a poodle clip, in accordance with implementations of the disclosure.

FIG. 8C illustrates a top view of a snap ring, in accordance with implementations of the disclosure.

FIG. 8D illustrates a top view of a wire ring, in accordance with implementations of the

FIG. 9 illustrates a cross-section of a stud pin and a retaining ring, in accordance with implementations of the disclosure.

FIG. 10 illustrates a cross-section of a stud pin having a horizontal pin retention mechanism, in accordance with implementations of the disclosure.

FIG. 11 illustrates a cross-section of a stud pin having a brazed or welded base for retention purposes, in accordance with implementations of the disclosure.

FIG. 12 illustrates a cross-section of a stud pin having a brazed/welded flat washer, in accordance with implementations of the disclosure.

FIG. 13A illustrates a cross-section of a stud pin having a retaining nut attached thereto, in accordance with implementations of the disclosure.

FIG. 13B illustrates a cross-section of a stud pin having a retaining nut attached thereto, in accordance with implementations of the disclosure.

### DETAILED DESCRIPTION OF THE INVENTION

A parallel plate capacitively coupled plasma reaction chamber typically consists of a vacuum chamber with an upper electrode assembly and a lower electrode assembly positioned therein. A substrate (usually a semiconductor) to be processed is covered by a suitable mask and placed directly on the lower electrode assembly. A process gas such as CF4, CHF3, CClF3, HBr, Cl2, SF6 or mixtures thereof is introduced into the chamber with gases such as O2, N2, He, Ar or mixtures thereof. The chamber is maintained at a pressure typically in the millitorr range. The upper electrode assembly includes a showerhead electrode with gas injection hole(s), which permit the gas to be uniformly dispersed through the upper electrode assembly into the chamber. One or more radio-frequency (RF) power supplies transmit RF power into the vacuum chamber and dissociate neutral process gas molecules into a plasma. Highly reactive radicals in the plasma are forced towards the substrate surface by an electrical field between the upper and lower electrodes. The surface of the substrate is etched or deposited on by chemical reaction with the radicals. The upper electrode assembly can include a single (monolithic) electrode or inner and outer electrodes, the monolithic electrode and inner electrode attached to a backing plate made of a different material. The monolithic/inner electrode is heated by the plasma and/or a heater arrangement during operation.

A showerhead electrode assembly can include a plurality of cam locks engaged with the interior of a mounting surface of the monolithic/inner electrode. The monolithic/inner electrode is attached to the backing plate by cam locks which fasten the monolithic/inner electrode to the backing plate at a plurality of positions distributed across the electrode. Such an assembly can include features as described in commonly owned U.S. Pat. Nos. 8,573,152 and 8,628,268, the disclosures of which are incorporated by reference herein.

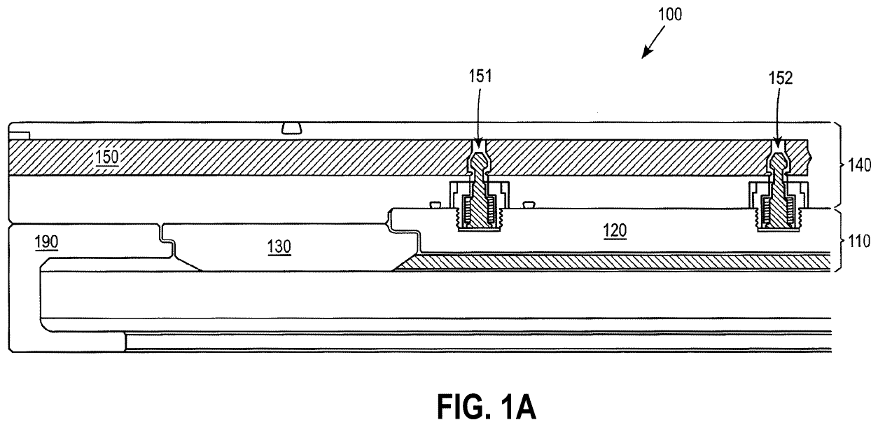

FIG. 1A shows a partial cross-sectional view of a portion of a showerhead electrode assembly 100 of a plasma reaction chamber for etching semiconductor substrates. As shown in FIG. 1A, the showerhead electrode assembly 100 includes an upper electrode 110, and a backing plate 140. The assembly 100 can also include a thermal control plate (not shown), a temperature controlled upper plate (top plate) (not shown) having liquid flow channels therein. The upper electrode 110 preferably includes an inner electrode 120, and an outer electrode 130. The upper electrode 110 can also be a monolithic showerhead electrode. The upper electrode 110 may be made of a conductive high purity material such as single crystal silicon, polycrystalline silicon, silicon carbide or other suitable material. The inner electrode 120 is a consumable part which must be replaced periodically. An annular shroud 190 with a C-shaped cross section surrounds the upper electrode 110. The cross section in FIG. 1A is along a cam shaft 150 shared by two cam locks 151 and 152 engaged on the inner electrode 120.

The showerhead electrode assembly 100 as shown in FIG. 1A is typically used with an electrostatic chuck (not shown) forming part of a flat lower electrode assembly on which a substrate is supported spaced 1 to 5 cm below the upper electrode 110. An example of a parallel plate type reactor is the Exelan™ dielectric etch reactor, made by Lam Research Corporation of Fremont, Calif. Such chucking arrangements provide temperature control of the substrate by supplying backside helium (He) pressure, which controls the rate of heat transfer between the substrate and the chuck.

During use, process gas from a gas source is supplied to the upper electrode 110 through one or more passages in the backing plate which permit process gas to be supplied to a single zone or multiple zones above the substrate.

The inner electrode 120 is preferably a planar disk or plate. The inner electrode 120 can have a diameter smaller than, equal to, or larger than a substrate to be processed, e.g., up to 300 mm, if the plate is made of single crystal silicon, which is the diameter of currently available single crystal silicon material used for 300 mm substrates. For processing 300 mm substrates, the outer electrode 130 is adapted to expand the diameter of the inner electrode 120 from about 12 inches to about 17 inches (as used herein, “about” refers to ±10%). The outer electrode 130 can be a continuous member (e.g., a single crystal silicon, polycrystalline silicon, silicon carbide or other suitable material in the form of a ring) or a segmented member (e.g., 2-6 separate segments arranged in a ring configuration, such as segments of single crystal silicon, polycrystalline silicon, silicon carbide or other material). To supply process gas to the gap between the substrate and the upper electrode 110, the inner electrode 120 is provided with a plurality of gas injection holes (not shown), which are of a size and distribution suitable for supplying a process gas, which is energized into a plasma in a reaction zone beneath the upper electrode 110.

Single crystal silicon is a preferred material for plasma exposed surfaces of the upper electrode 110. High-purity, single crystal silicon minimizes contamination of substrates during plasma processing as it introduces only a minimal amount of undesirable elements into the reaction chamber, and also wears smoothly during plasma processing, thereby minimizing particles.

Alternative materials including composites of materials that can be used for plasma-exposed surfaces of the upper electrode 110 include polycrystalline silicon, Y2O3, SiC, Si3N4, and AlN, for example.

In an embodiment, the showerhead electrode assembly 100 is large enough for processing large substrates, such as semiconductor substrates having a diameter of 300 mm. For 300 mm substrates, the inner electrode 120 is at least 300 mm in diameter. However, the showerhead electrode assembly 100 can be sized to process other substrate sizes.

The backing plate 140 is preferably made of a material that is chemically compatible with process gases used for processing semiconductor substrates in the plasma processing chamber, has a coefficient of thermal expansion closely matching that of the electrode material, and/or is electrically and thermally conductive. Preferred materials that can be used to make the backing plate 140 include, but are not limited to, graphite, SIC, aluminum (Al), or other suitable materials.

The backing plate 140 is preferably attached to the thermal control plate with suitable mechanical fasteners, which can be threaded bolts, screws, or the like. For example, bolts can be inserted in holes in the thermal control plate and screwed into threaded openings in the backing plate 140. The thermal control plate is preferably made of a machined metallic material, such as aluminum, an aluminum alloy or the like. The upper temperature controlled plate is preferably made of aluminum or an aluminum alloy.

The outer electrode 130 and the annular shroud 190 can be mechanically attached to the backing plate 140 by cam locks. FIG. 1B shows a cross section of the showerhead electrode assembly 100 along another cam shaft 160 shared by two cam locks 161 and 162 engaged on the annular shroud 190 and the outer electrode 130, respectively.

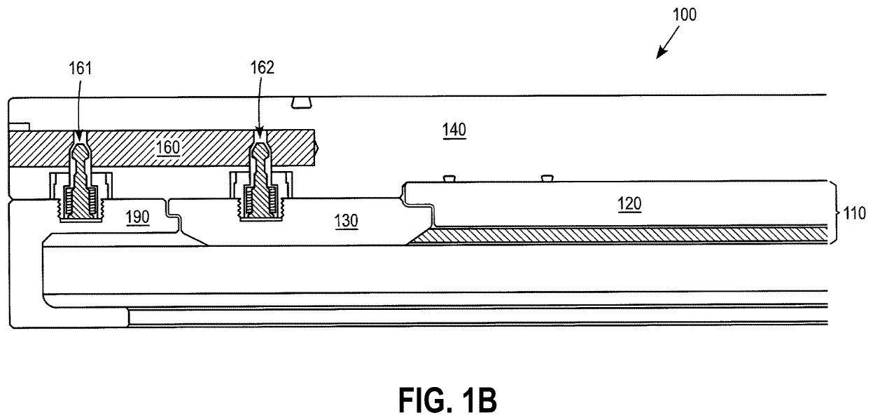

With reference to FIG. 2A, a three-dimensional view of an exemplary cam lock includes portions of the outer electrode 130 or the inner electrode 120 or the annular shroud 190, and the backing plate 140. The cam lock is capable of quickly, cleanly, and accurately attaching the outer electrode 130, inner electrode 1210 or the annular shroud 190 to the backing plate 140.

The cam lock includes a stud pin (locking pin) 205 mounted into a socket 213. The stud pin may be surrounded by a disc spring stack 215, such as, for example, stainless steel Belleville washers. The stud pin 205 and disc spring stack 215 may then be press-fit into the socket 213. The stud pin 205 and the disc spring stack 215 are arranged into the socket 213 such that a limited amount of lateral movement is possible between the outer electrode 130 or the inner electrode 120 or the annular shroud 190, and the backing plate 140. Limiting the amount of lateral movement allows for a tight fit between the outer electrode 130 or the inner electrode 120 or the annular shroud 190, and the backing plate 140, thus ensuring good thermal contact, while still providing some movement to account for differences in thermal expansion between the two parts.

In a specific exemplary embodiment, the socket 213 is fabricated from high strength Torlon®. Alternatively, the socket 213 may be fabricated from other materials possessing certain mechanical characteristics such as good strength and impact resistance, creep resistance, dimensional stability, radiation resistance, and chemical resistance may be readily employed. Various materials such as polyamide-imide, acetals, and ultra-high molecular weight polyethylene materials may all be suitable. High temperature-specific plastics and other related materials are not required for forming the socket 213 as 230° C. is a typical maximum temperature encountered in applications such as etch chambers. Generally, a typical operating temperature is closer to 130° C.

The cam shaft 160 or 150 is mounted into a bore machined into the backing plate 140. In a typical application for an etch chamber designed for 300 mm semiconductor substrates, eight or more cam shafts may be spaced around the periphery of the backing plate 140.

The stud pin 205 and cam shaft 160 or 150 may be machined from stainless steel (e.g., 316, 316L, 17-7, NITRONIC-60, etc.) or any other material providing good strength and corrosion resistance.

Referring now to FIG. 2B, a cross-sectional view of the cam lock further exemplifies how the cam lock operates by pulling the outer electrode 130, the inner electrode 120 or the annular shroud 190 in close proximity to the backing plate 140. The stud pin 205/disc spring stack 215/socket 213 assembly is mounted into the outer electrode 130, the inner electrode 120 or the annular shroud 190. As shown, the assembly may be screwed, by means of external threads on the socket 213 into a threaded socket in the outer electrode 130, the inner electrode 120 or the annular shroud 190.

The socket 213 has an external thread and a hexagonal top member allowing for easy insertion into the outer electrode 130, the inner electrode 120 or the annular shroud 190 (see FIGS. 2A and 2B) with light torque (e.g., in a specific exemplary embodiment, about 20 inch-pounds). As indicated above, the socket 213 may be machined from various types of plastics. Using plastics minimizes particle generation and allows for a gall-free installation of the socket 213 into a mating socket on the outer electrode 130, the inner electrode 120 or the annular shroud 190.

For example, with continued reference to FIGS. 2A and 2B, the cam lock is assembled by inserting the cam shaft 160 or 150 into a backing plate bore 211. The cam shaft 160 or 150 has two internal eccentric cutouts. In the cam shaft 160, one cutout engages an enlarged head of a stud pin 205 on the outer electrode 130 and the other cutout engages an enlarged head of a stud pin 205 on the annular shroud 190. In the cam shaft 150, each of the two cutouts engages an enlarged head of a stud pin 205 on the inner electrode 120. The cam shaft 160 or 150 may first be turned in one direction through use of a hex opening in some implementations, for example, counter-clockwise, to allow entry of the stud pins 205 into the cam shaft 160 or 150, and then turned clockwise to fully engage and lock the stud pins 205. The clamp force required to hold the outer electrode 130, the inner electrode 120 or the annular shroud 190 to the backing plate 140 is supplied by compressing the disc spring stacks 215 beyond their free stack height. As the disc spring stacks 215 compress, the clamp force is transmitted from individual springs in the disc spring stacks 215 to the sockets 213 and through the outer electrode 130, the inner electrode 120 or the annular shroud 190 to the backing plate 140.

In an exemplary mode of operation, the cam shaft 160 or 150 is inserted into the backing plate bore 211. The cam shaft 160 or 150 is rotated counterclockwise to its full rotational travel. The stud/socket assemblies lightly torqued into the outer electrode 130, the inner electrode 120 and/or the annular shroud 190 are then inserted into vertically extending through holes below the horizontally extending backing plate bore 211 such that the heads of the stud pins 205 engage in the eccentric cutouts in the cam shaft 160 or 150. The outer electrode 130, the inner electrode 120 or the annular shroud 190 is held against the backing plate 140 and the cam shaft 160 or 150 is rotated clockwise to engage and lock the stud pins 205. The exemplary mode of operation may be reversed to dismount the outer electrode 130, the inner electrode 120 or the annular shroud 190 from the backing plate 140.

The stud-socket assembly in accordance with implementations of the disclosure is now described in greater detail with reference to the following drawings.

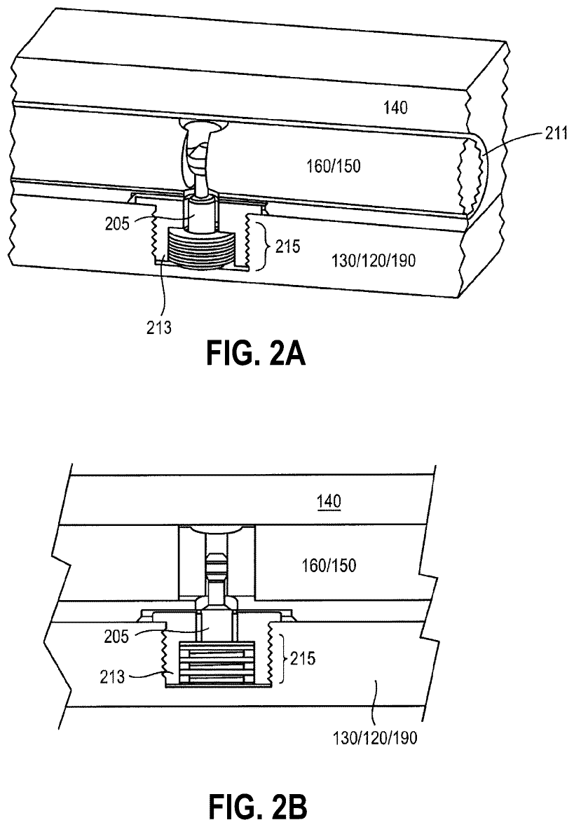

FIG. 3 is a cross-sectional view of a stud-socket assembly, in accordance with implementations of the disclosure.

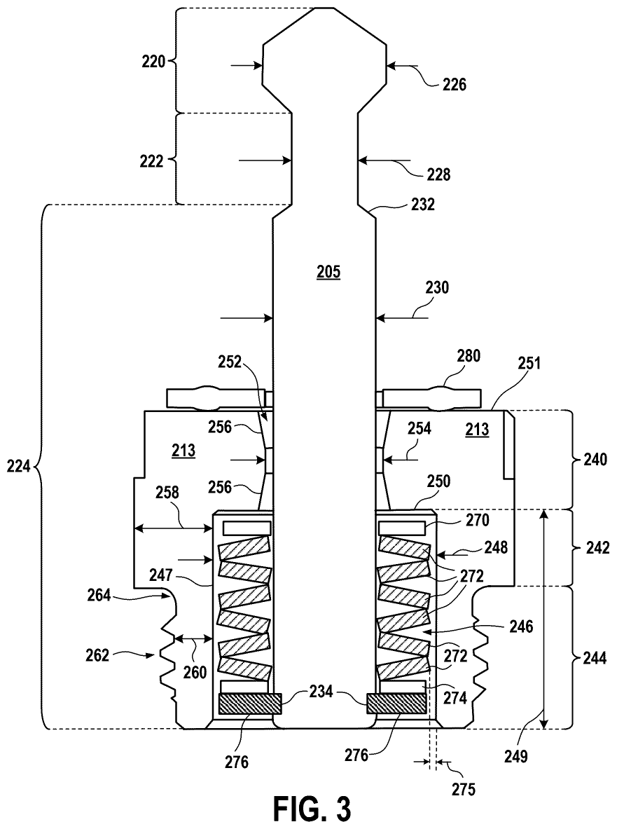

FIG. 4 is a plan view of a stud-socket assembly, in accordance with implementations of the disclosure.

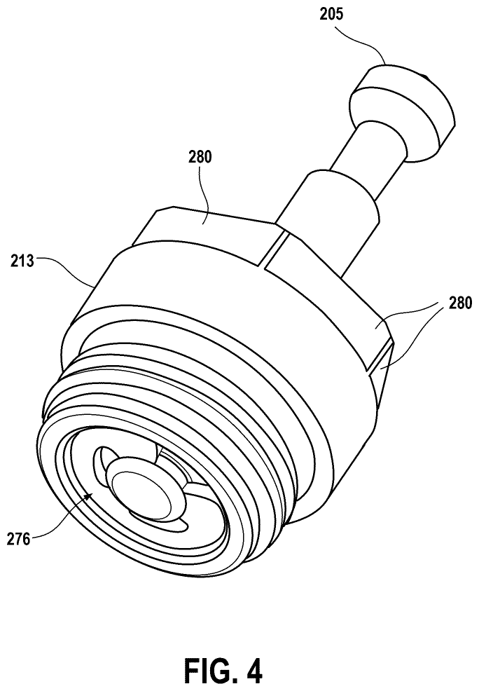

FIG. 5A is a cutaway side view of a socket, in accordance with implementations of the disclosure.

FIG. 5B is a cutaway perspective view of a socket, in accordance with implementations of the disclosure.

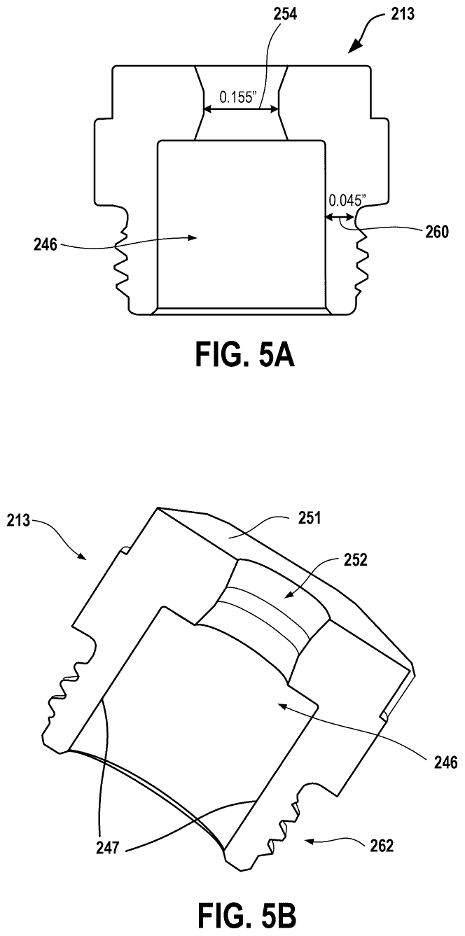

FIG. 6 is a schematic cross-section of a stud pin, in accordance with implementations of the disclosure.

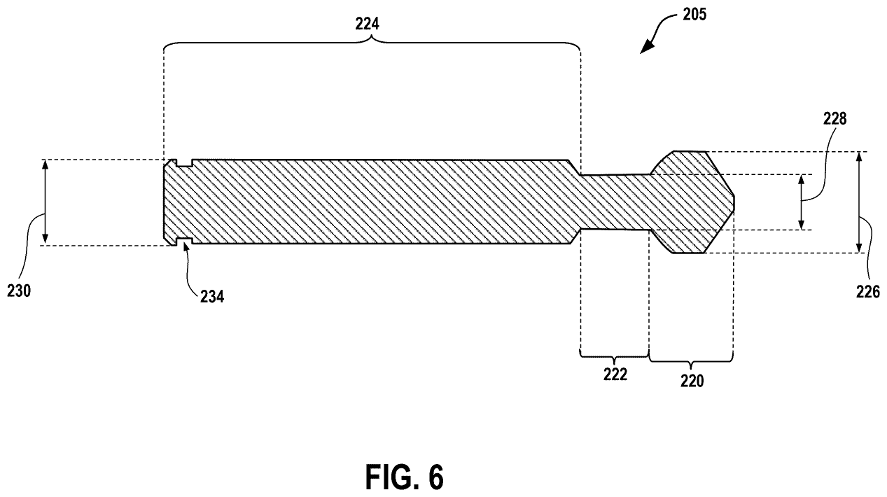

FIG. 7A is a cross-sectional view of a stud-socket assembly in an installed configuration, in accordance with implementations of the disclosure.

FIG. 7B is a cross-sectional view of a stud-socket assembly in an installed configuration, in accordance with implementations of the disclosure.

Broadly speaking, the stud-socket assembly of the present disclosure includes a stud pin 205, a socket 213, an E-clip 276, and a plurality of spring washers 272. The stud-socket assembly may further include flat washers 270 and 274. In some implementations, the stud-socket assembly further includes a gasket 280.

Stud pin 205 includes a head portion 220, neck portion 222, and main body 224. The head portion 220 is shaped having an outer diameter 226 along its mid-section, with the diameter tapering towards the top and bottom of the head portion 220. In some implementations, the outer diameter 226 of the head portion 220 is in the range of about 0.16 to 0.17 inch; in some implementations, the outer diameter 226 is about 0.164 inch.

The neck portion 222 is cylindrical and has a diameter 228. The neck portion 222 connects the head portion 220 to a main body 224. In some implementations, the diameter 228 of the neck portion 222 is in the range of about 0.08 to 0.1 inch; in some implementations, the diameter 228 is approximately 0.09 inch.

The main body 224 is substantially cylindrically shaped, having a shoulder 232 at the top end of the main body 224, and having a groove 234 at the bottom end of the main body 224. The groove 234 is engaged by an E-clip 276 as shown. The portion of the main body 224 extending from the shoulder 232 to the groove 234, has a constant diameter 230. In some implementations, the diameter 230 is in the range of about 0.135 to 0.14 inch; in some implementations, the diameter 230 is about 0.138 inch.

In some implementations, the groove 234 has a diameter in the range of about 0.11 to 0.12 inch; in some implementations, the groove 243 has a diameter of about 0.116 inch. In some implementations, the groove 243 is defined having a depth of indentation of about 0.01 to 0.013 inch; or in some implementations, a depth of indentation of about 0.011 inch (depth relative to the outer surface diameter 230 of the main body 224).

In some implementations, the outer diameter 226 of the head portion 220 is greater than the diameter 230 of the main body 224 by about 0.02 to 0.03 inch; in some implementations, the outer diameter 226 of the head portion 220 is greater than the diameter 230 of the main body 224 by about 0.026 inch.

A socket 213 includes a top section 240, a middle section 242, and a bottom section 244. The middle section 242 and the bottom section 244 are tubular-shaped sections that circumferentially surround a cylindrical interior volume (or cavity) 246 of the socket 213, such that the middle section 242 and the bottom section 244 have the same inner diameter 248 which defines the sidewall 247 of the cylindrical interior volume 246. In some implementations, the inner diameter 248 is in the range of about 0.29 to 0.3 inch; in some implementations, the inner diameter 248 is about 0.295 inch.

At the (planar) intersection of the top section 240 and the middle section 242 a top surface 250 of the cylindrical interior volume 246 is defined, the top surface 250 further defining a ceiling of the cylindrical interior volume 246. In some implementations, the height 249 of the cylindrical interior volume 246 is in the range of about 0.250 to 0.350; in some implementations, the height 249 of the cylindrical interior volume 246 is about 0.300. It will be appreciated that in some implementations, the height 249 of the cylindrical interior volume 246 is equivalent to the sum of the heights of the middle section 242 and bottom section 244 of the socket 213.

The top section 240 is a disc-shaped section extending above the top surface 250 of the cylindrical interior volume 246. The top section 240 has an opening 252 through which the stud pin 205 is disposed. More specifically, during operation of the assembly when installed, the top section 240 circumferentially surrounds the main body 224 of the stud pin 205. In some implementations, the opening 252 has an inner diameter 254 in the range of about 0.15 to about 0.16 inch; in some implementations, the opening 252 has an inner diameter 254 of about 0.155 inch. In some implementations, the opening 252 has an inner diameter 254 that is less than the outer diameter 226 of the head portion 220 of the stud pin 205 by at least 0.005 or 0.009 or 0.01 inch.

A stack of spring washers 272 (also called Belleville washers) are fitted to the stud pin 205, and more specifically, spring washers 272 are configured to circumferentially surround the main body 224 of the stud pin 205 when the stud-socket assembly is installed. A flat washer 270 is fitted immediately above the spring washers 272, between the spring washers 272 and the top surface 250 of the cylindrical interior volume 246, and circumferentially surrounding the main body 224. A flat washer 274 is fitted immediately below the spring washers 272 (between the spring washers 272 and the E-clip 276) and also circumferentially surrounding the main body 224. The flat washers 272 and 274 act as thrust washers to distribute the load (along the ceiling of the interior cylindrical volume and along the E-clip) when the stud pin is engaged by the cam shaft and the spring washers are compressed.

It will be appreciated that the flat washers and spring washers are configured to be disposed within the cylindrical interior volume 246 when the stud-socket assembly is installed. The flat washers and spring washers are vertically constrained between the ceiling of the cylindrical interior volume 246 and the E-clip 276, and horizontally constrained by the main body 224 shaft of the stud pin 205.

In the illustrated implementation, the stack of spring washers 272 consists of six spring washers arranged in series. However, in other implementations, there may be more or fewer spring washers, which can be arranged in series, in parallel, or include a mixture of arrangements in series and parallel. In some implementations, each of the spring washers has an overall height of about 0.03 to 0.035 inch; or in some implementations, an overall height of about 0.032 inch. In some implementations, the spring washers 272 define the previously described disc spring stack 215, which may also optionally include the flat washers 272/274.

In various implementations, the flat washers and/or spring washers are made of a suitable material, such as a nickel alloy (e.g. Inconel).

In some implementations, the E-clip 276 has a thickness in the range of about 0.02 to 0.03 inch; or in some implementations, a thickness of about 0.025 inch. It will be appreciated that the (longitudinal) width of the groove 234 is sized accordingly to accommodate the thickness of the E-clip 276 (e.g. about 0.002 to 0.003 inch greater than the thickness of the E-clip).

It will be appreciated that as the diameter 230 of the main body 224 is constant along the portion that the flat washers and spring washers are disposed, then there is no risk of the flat washers or spring washers shifting horizontally or becoming horizontally misaligned, except as permitted based on the diameters of the flat washers and spring washers relative to the stud pin 205. In some implementations, the inner diameter of the flat washers and/or spring washers is in the range of about 0.14 to 0.145 inch; in some implementations, the inner diameter of the flat washers and/or spring washers is about 0.142 inch.

Furthermore, a prior implementation of the stud pin included portions with different diameters, including a portion with a diameter greater than the diameter of the top opening of the socket, but disposed below the top opening. This meant that when the stud pin was engaged by a cam and consequently lifted, if for some reason the stud pin was lifted higher than normal, there could be a possibility of the stud pin potentially being blocked/pulled against the underside of the top opening of the socket. However, in accordance with implementations of the present disclosure, the main body 224 of the stud pin 205 has a largely constant diameter as previously described, that is less than the diameter of the opening 252, so that there is no possibility of the stud pin 205 being blocked/pulled against the underside of the opening 252. Also, the contour of the opening 252 does not need to be shaped in any particular way in order to accommodate the vertical movement of the stud pin 205, other than having a diameter throughout its extent that is greater than the diameter 230 of the main body 224 of the stud pin 205.

In some implementations, the outer diameter of the flat washers and/or spring washers is in the range of about 0.28 to 0.285 inch; in some implementations, the outer diameter of the flat washers and/or spring washers is about 0.281 inch. In some implementations, the inner diameter 248 of the cylindrical interior volume 246 is in the range of about 0.29 to 0.3 inch; in some implementations, the inner diameter 248 of the cylindrical interior volume 246 is about 0.295 inch.

Thus, there is defined a radial gap/clearance 275 between the outer diameter of the flat washers and/or spring washers, and the sidewall 247 of the cylindrical interior volume 246 (as defined by the inner diameter 248 of the cylindrical interior volume 246). In some implementations, this radial gap 275 is in the range of about 0.005 to 0.01 inch; in some implementations, the radial gap is about 0.007 inch.

The bottom section 244 of the socket 213 has an external surface 262 that is threaded, to enable the socket 213 to be screwed into a corresponding threaded opening, such as a threaded opening in the inner electrode 120, outer electrode 130, or annular shroud 190. In some implementations, the top section 240 is formed with an indented hex head 280 (e.g. shown at FIG. 4) or other indented form, to facilitate the socket 213 being screwed into the threaded opening as described.

The bottom section 244 of the socket 213 has a thickness 260. In some implementations, the thickness 260 of the bottom section 244 is in the range of about 0.045 to 0.05 inch; in some implementations, the thickness 260 of the bottom section 244 is about 0.048 inch.

The middle section 242 of the socket 213 has a radial thickness 258. In some implementations, the radial thickness 258 of the middle section 242 is in the range of about 0.75 to 1.25; in some implementations, the radial thickness 258 of the middle section 242 is about 0.100 inch.

In a prior implementation of the stud pin and socket, the diameter of the socket's opening was configured to be only about 0.0005 to 0.0017 inch smaller than the outer diameter of the head of the stud pin. This was required to enable the stud pin to be press-fit through the opening from the underside of the socket. However, during the lifetime (e.g. approximately 1800 RF hours of use in a plasma process chamber) of the assembly, the opening may erode and become larger, possibly to the point where the diameter of the opening is larger than the diameter of the stud pin's head. This can pose a challenge when changing the assembly, as the stud pin may fall through the enlarged opening, and the washers may become dislodged from the assembly.

In contrast to the prior implementation, in the present implementation, the diameter of the socket's opening 252 is significantly smaller than the outer diameter 226 of the stud pin's head portion 220, such that a significant interference fit is provided, so that the stud pin 205 cannot be press-fit through the socket's opening from the underside as was previously required. Instead the stud pin 205 is inserted from the top side of the socket 213, and the washers and E-clip are subsequently fitted to the stud pin 205. The degree of the interference between the socket opening 252 and the stud pin head portion 220 is configured to be large enough to prevent the diameter of the opening 252 from becoming larger than the stud pin head's outer diameter 226 over the course of its lifetime (e.g. during an approximate 1800 RF hour lifetime). In this manner, there is no risk of the stud pin falling through the opening when the stud-socket assembly is replaced. For example, the opening 252 may have an inner diameter 254 that is less than the outer diameter 226 of the head portion 220 of the stud pin 205 by at least about 0.005 to 0.01 inch; or in some implementations, at least about 0.007 to 0.009 inch.

At the intersection 264 where the outer surface of the bottom section 244 meets the bottom surface of the middle section 242, a radiused (curved) contour is defined. The radiused contour of the intersection 264 provides enhanced strength at the intersection 264, helping to reduce the possibility of breakage of the socket 213 in this region. In some implementations, the radiused contour has a radius of curvature in the range of about 0.015 to 0.025 inch; or in some implementations, a radius of curvature of about 0.020 inch.

In some implementations, the opening 252 has a tapered contour 256 so that the sidewalls of the opening 252 are flared outwards towards the top and bottom of the opening 252, and wherein its inner diameter 254 in the middle is less than the inner diameter of the opening 252 at the top or bottom of the opening 252. In some implementations, the opening 252 is chamfered or beveled at the top and bottom. The tapered contour 256 provides taper relief for the stud pin to allow the stud pin 205 a certain amount of articulation or tilting and prevents binding due to non-vertical loading. This is particularly important when the inner diameter 254 is designed, as described above, to be significantly smaller than the outer diameter 226 of the stud pin's head portion 220 such that a significant interference fit is provided to prevent the stud pin falling through the opening during replacement, even when the opening has been eroded and become larger. For example, FIG. 7B conceptually illustrates tilting of the stud pin 205 within the socket 213, as accommodated by the tapered contour 256 of the opening 252. In some implementations, the tapered contour 256 is configured to enable tilting of the stud pin 205 by up to about 3 degrees off vertical.

In some implementations, the stud pin is fabricated from a material having a lower hardness than that of the cam shaft. For example, in some implementations, the cam shaft is fabricated from Nitronic 60, whereas the stud pin is fabricated from a lower hardness stainless steel (e.g. 316L). In this manner, any potential wear is more likely to occur on the stud pin as opposed to the cam shaft, which is desirable as the stud pin is a consumable part (part of the stud-socket assembly, which is consumable) and intended to be replaced at regular intervals, whereas the cam shaft is not a consumable.

In some implementations, the stud-socket assembly includes a gasket 280, which can be formed from a compliant material, and functions to seal the interior of the socket and the stud pin from exposure to process gases when the stud-socket assembly is installed.

Although in some implementations, the aforementioned E-clip 276 is fitted to groove 234 in order to secure the disc spring stack (flat and Belleville washers) inside the cylindrical volume of the socket, in other implementations, other form factors and mechanisms can be employed to retain the disc spring stack on the stud pin.

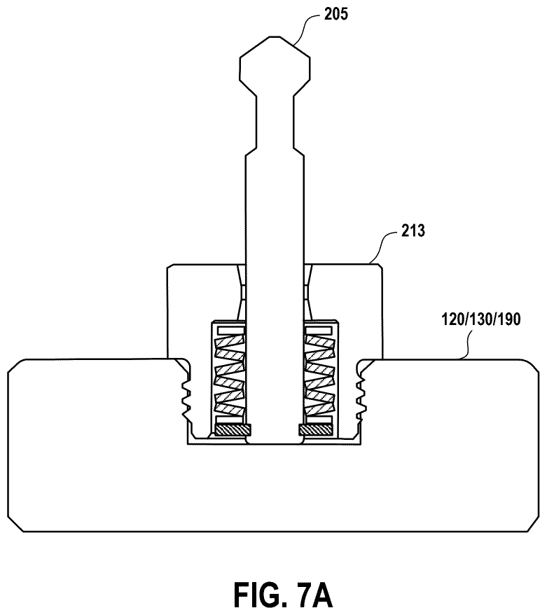

It will be appreciated that an E-clip is one type of retaining ring, and in other implementations, other types of retaining rings can be used in place of an E-clip, such as a poodle clip, a snap ring, a wire ring, etc., which can be fitted to an appropriately shaped grove such as a rectangular-shaped groove such as groove 234 or another type of groove such as a semicircular-shaped groove. By way of example without limitation, FIGS. 8A, 8B, 8C, and 8D illustrate various types of retaining rings which can be used to secure the disc spring stack to the stud pin.

FIG. 8A illustrates a top view of an E-clip, in accordance with implementations of the disclosure.

FIG. 8B illustrates a top view of a poodle clip, in accordance with implementations of the disclosure.

FIG. 8C illustrates a top view of a snap ring, in accordance with implementations of the disclosure.

FIG. 8D illustrates a top view of a wire ring, in accordance with implementations of the disclosure. In some implementations, the wire ring has a rectangular or square cross-section. In other implementations, the wire ring can have a circular cross-section (that mates to a correspondingly shaped semi-circular groove on the stud pin).

It will be appreciated that the inner diameter of the retaining ring will be configured to fit that of the corresponding groove on the stud pin. Furthermore, the various dimensions of the retaining ring (e.g. thickness, inner diameter, outer diameter) and the corresponding groove can be configured to provide a sufficient load rating to bear the forces present when the stud-socket assembly is under load when placed in operation. While specific examples of a retaining ring and groove are described herein, it will be appreciated that these are provided by way of example without limitation, and that the stud-socket assembly can be configured to use any type of retaining ring and corresponding groove combination having sufficient load rating and capability for retaining the disc spring stack in accordance with implementations of the disclosure.

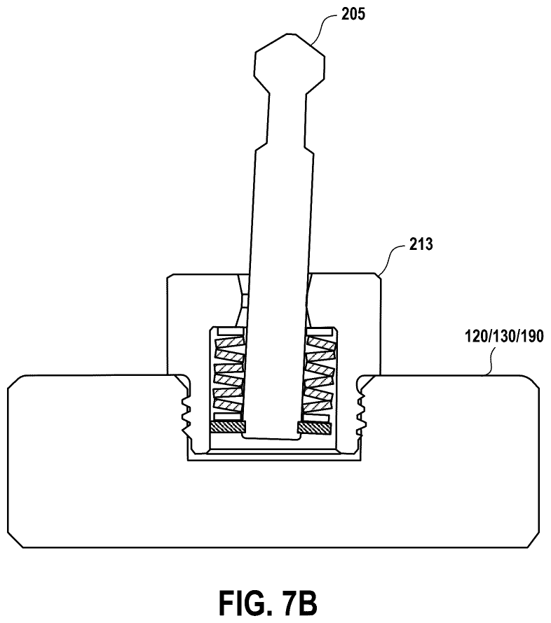

FIG. 9 illustrates a cross-section of a stud pin and a retaining ring, in accordance with implementations of the disclosure. In the illustrated implementation, the retaining ring 900 has a round cross-sectional shape and is seated in a semi-circular groove 902 at the bottom portion of the stud pin 205. In some implementations, the retaining ring 900 is a snap ring or a wire ring.

While a retaining ring fitted to a groove is one type of mechanism enabling assembly of the stud-socket assembly by insertion of the stud pin through the top of the socket, it will be appreciated that other mechanisms for retaining the disc spring stack after insertion of the stud pin are possible.

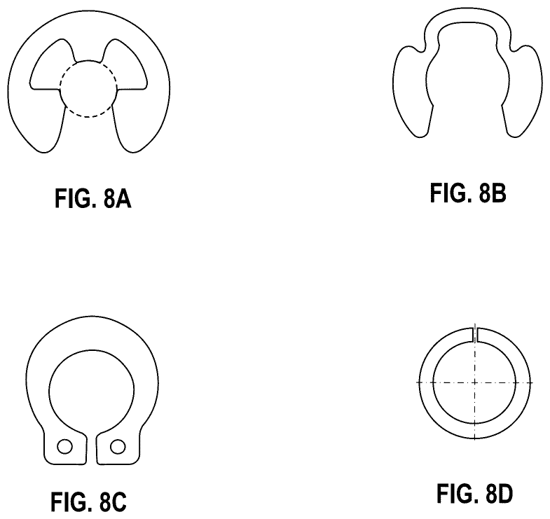

FIG. 10 illustrates a cross-section of a stud pin having a horizontal pin retention mechanism, in accordance with implementations of the disclosure. In the illustrated implementation, a retaining pin 1000 is inserted through a through-hole 1002 to retain the disc spring stack. That is, the retaining pin 1000 is inserted after the disc spring stack is fitted to the stud pin during assembly of the stud-socket assembly.

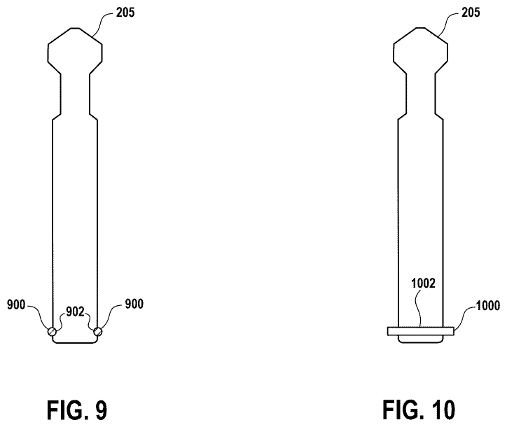

FIG. 11 illustrates a cross-section of a stud pin having a brazed or welded base for retention purposes, in accordance with implementations of the disclosure. In the illustrated implementation, a base 1100 is brazed or welded to the bottom end of the main body of the stud pin 205, and serves to retain the disc spring stack once assembled. In the illustrated implementation, the base 1100 is brazed or welded along a braze/weld line 1102. In some implementations, the base 1100 is disc-shaped. In other implementations, the base 1100 need not be specifically disc-shaped, provided the base 1100 provides sufficient flanged regions extending beyond the diameter of the stud pin main body, to provide retention of the disc spring stack under load during operation.

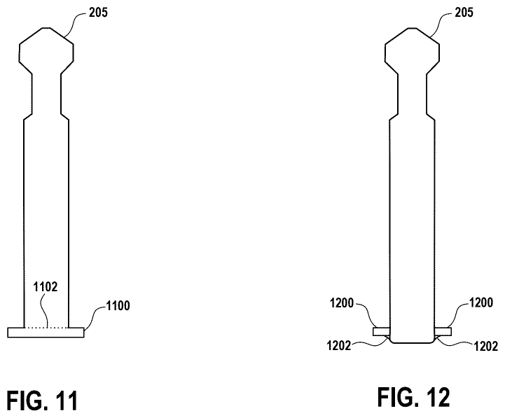

FIG. 12 illustrates a cross-section of a stud pin having a brazed/welded flat washer, in accordance with implementations of the disclosure. In the illustrated implementation, a flat washer 1200 is brazed or welded to the stud pin 205 near the bottom end of the main body of the stud pin. In the illustrated implementation the flat washer 1200 is more specifically secured to the stud pin with a filler material 1202 that has been brazed or welded. In some implementations, the flat washer 1200 can be the bottom flat washer of the disc spring stack previously described (flat washer 274). In other implementations, the flat washer 1200 can be an additional separate flat washer.

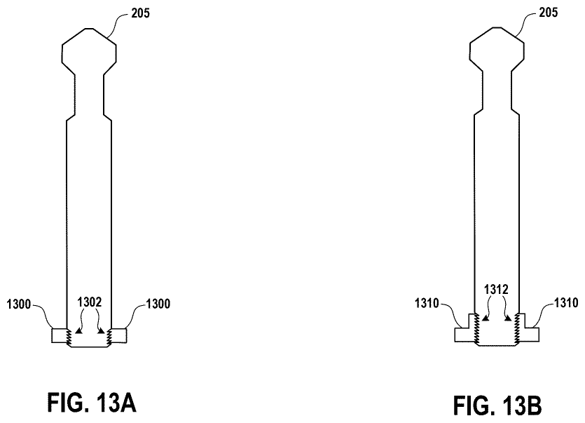

FIG. 13A illustrates a cross-section of a stud pin having a retaining nut attached thereto, in accordance with implementations of the disclosure. In some implementations, the bottom end of the stud pin 205 is threaded (ref. 1302) so as to enable a retaining nut 1300 to be screwed onto the end of the stud pin 205, and thereby provide retention of the disc spring stack. In some implementations, the retaining nut 1300 is a round nut or a hexagonal nut, or another shaped nut. In some implementations, the retaining nut 1300 is a flanged nut with its upper portion being flanged to provide additional surface region to engage the bottom (e.g. flat washer) of the disc spring stack.

FIG. 13B illustrates a cross-section of a stud pin having a retaining nut attached thereto, in accordance with implementations of the disclosure. In the illustrated implementation, the retaining nut 1310 is a flanged nut, but with the flanged portion being at the bottom of the retaining nut 1310. This configuration enables a taller threaded portion along the shaft of the stud pin and the interior of the retaining nut 1310 (as compared to the implementation of FIG. 3A) to be utilized for providing improved secure mating between the retaining nut 1310 and the stud pin 205, while accommodating the height of the disc spring stack.

1. A stud-socket assembly for connecting an upper electrode or annular shroud to a backing plate in a plasma process chamber, comprising:
a stud pin having a head portion, a main body, and a neck portion that connects the head portion to the main body;
wherein the neck portion being a cylindrical portion having a first diameter;
wherein the main body being substantially cylindrically shaped at a second diameter that is greater than the first diameter, and having a shoulder at a first end that connects to the neck portion, and a second end opposite the first end;
wherein the head portion having an outer diameter that is greater than the second diameter;
a socket having a cylindrical interior volume, and having an upper opening through which the stud pin is disposed, the upper opening having an inner diameter that is less than the outer diameter of the head portion of the stud pin by at least 0.005 inch;
a plurality of Belleville washers that circumferentially surround the main body of the stud pin;
a retainer attached to the second end of the main body of the stud pin, the retainer configured to retain the plurality of Belleville washers within the cylindrical interior volume of the socket.

2. The stud-socket assembly of claim 1, wherein the inner diameter of the upper opening being less than the outer diameter of the head portion of the stud pin defines an interference such that the head portion cannot be press fit through the opening for assembly.

3. The stud-socket assembly of claim 1, wherein the head portion of the stud pin is configured to be engaged by a camshaft disposed in the backing plate.

4. The stud-socket assembly of claim 1, wherein an external surface of the socket being threaded to enable the socket to be screwed into the upper electrode.

5. The stud-socket assembly of claim 1, further comprising:
a first flat washer disposed between the Belleville washers and the retainer;
a second flat washer disposed between the Belleville washers and the upper opening of the socket.

6. The stud-socket assembly of claim 1, wherein the upper opening of the socket having taper relief that facilitates tilting articulation of the stud pin.

7. The stud-socket assembly of claim 1, wherein the Belleville washers are arranged in series.

8. The stud-socket assembly of claim 1, wherein the socket is fabricated from a Torlon material.

9. The stud-socket assembly of claim 1, wherein the stud pin is fabricated from a stainless steel material.

10. The stud-socket assembly of claim 1, wherein the retainer is one of an E-clip, a poodle clip, or a snap ring.

11. A stud-socket assembly for connecting an upper electrode or annular shroud to a backing plate in a plasma process chamber, comprising:
a stud pin having a head portion, a main body, and a neck portion that connects the head portion to the main body;
wherein the neck portion being a cylindrical portion having a first diameter;
wherein the main body being substantially cylindrically shaped at a second diameter that is greater than the first diameter, and having a first end that connects to the neck portion, and a second end opposite the first end;
wherein the head portion having an outer diameter that is greater than the second diameter;
a socket having a cylindrical interior volume, and having an upper opening through which the stud pin is disposed, the upper opening having an inner diameter that is less than the outer diameter of the head portion of the stud pin by at least 0.005 inch;
a plurality of Belleville washers that circumferentially surround the main body of the stud pin;
wherein the socket having a lower opening, an inner diameter of the lower opening being greater than an outer diameter of the Belleville washers;
a retainer attached to the second end of the main body of the stud pin, the retainer configured to retain the plurality of Belleville washers within the cylindrical interior volume of the socket.

12. The stud-socket assembly of claim 11, wherein the inner diameter of the upper opening being less than the outer diameter of the head portion of the stud pin defines an interference such that the head portion cannot be press fit through the opening for assembly.

13. The stud-socket assembly of claim 11, wherein the head portion of the stud pin is configured to be engaged by a camshaft disposed in the backing plate.

14. The stud-socket assembly of claim 11, wherein an external surface of the socket being threaded to enable the socket to be screwed into the upper electrode.

15. The stud-socket assembly of claim 11, further comprising:
a first flat washer disposed between the Belleville washers and the retainer;
a second flat washer disposed between the Belleville washers and the upper opening of the socket.

16. The stud-socket assembly of claim 11, wherein the upper opening of the socket having taper relief that facilitates tilting articulation of the stud pin.

17. The stud-socket assembly of claim 1, wherein the Belleville washers are arranged in series.

18. The stud-socket assembly of claim 1, wherein the main body of the stud pin having a circumferential groove defined at the second end of the main body, and wherein the retainer is fitted to the circumferential groove.

19. The stud-socket assembly of claim 18, wherein the circumferential groove has a substantially rectangular or substantially semi-circular cross-section.

20. The stud-socket assembly of claim 11, wherein the retainer is one of an E-clip, a poodle clip, or a snap ring.
